(19) United States
(12) Patent Application Publication
(10) Pub. No.: US 2003/0057560 A1
(43) Pub. Date: Mar. 27, 2003

(54) Thermoelectric device and optical module made with the device and method for producing them

(76) Inventors: Nobuyoshi Tatoh, Itami-shi (JP); Jing-Feng Li, Sendai-shi (JP); Ryuzo Watanabe, Sendai-shi (JP); Shuji Tanaka, Sendai-shi (JP); Masayoshi Esashi, Sendai-shi (JP)

Correspondence Address: MCDERMOTT WILL & EMERY, 600 13TH STREET, N.W., WASHINGTON, DC, 20005-3096, US

(21) Appl. No.: 10/100,191

(22) Filed: Mar. 19, 2002

(30) Foreign Application Priority Data
Sep. 25, 2001 (JP) 2001-291222

(51) Int. Cl. H01L 27/16; H01L 23/15

(52) U.S. Cl. 257/773; 257/786; 257/779; 257/768; 438/25

(57) ABSTRACT

A thermoelectric device that realizes miniaturization and densification, an optical module incorporating the thermoelectric device, and their production method. N-type thermoelectric elements 51 and p-type thermoelectric elements 52 are arranged orthogonally and alternately, on the XY-plane, in a matrix consisting of at least four elements in total in a row and at least four elements in total in a column. All the thermoelectric elements 51 and 52 have a size of at most 250 μm in the X and Y directions. At most four thermoelectric elements nearest to an n-type thermoelectric element 51 are of p type, and at most four thermoelectric elements nearest to a p-type thermoelectric element 52 are of n type. The thermoelectric elements 51 and 52 are bonded through metallic bonding materials to electrodes 53 having the shape of a rectangle or a rounded rectangle formed on an insulating substrate 54.

### BACKGROUND OF THE INVENTION

1. Field of the Invention

The present invention relates to (a) a thermoelectric device used for thermal power generation, which converts thermal energy into electric power, and electronic cooling through the Peltier effect and (b) an optical module for optical communication incorporating the thermoelectric device.

2. Description of the Background Art

Thermoelectric devices are used for generating power by using the otherwise useless heat generated in a computer or an automobile and as a device for cooling ICs in a computer or laser-diodes (LDs) for optical communication. Such thermoelectric devices are produced by coupling a multitude of n-type and p-type thermoelectric elements through electrodes made of, for example, metal. Their structures are broadly classified into two types.

One type is represented by a thermoelectric device described in the published Japanese utility-model application Jitsukaishou 59-91765, for example. This type is referred to as Thermoelectric device A. FIG. 8 shows Thermoelectric device A together with the definition of the X, Y, and Z directions. This definition shall be applied to all the relevant portions in this specification, including the claims. In Thermoelectric device A, n-type thermoelectric elements 1 and p-type thermoelectric elements 2 are arranged alternately in a matrix. Couples of neighboring thermoelectric elements 1 and 2 are connected either at their top faces or at their bottom faces through an electrode 3 provided on an insulating substrate 4. The electrodes 3 at both ends have a lead 5.

More specifically, the thermoelectric elements 1 and 2 are orthogonally arranged on the XY-plane such that at least four elements in total are arranged in a row and at least four elements in total are arranged in a column. At most four thermoelectric elements nearest to an n-type thermoelectric element 1 are of p type, and at most four thermoelectric elements nearest to a p-type thermoelectric element 2 are of n type. The thermoelectric elements 1 and 2 are connected with an electrode 3 at their top and bottom faces on the XY-plane. The electrodes 3 are formed on a substrate 4 made of a ceramic insulator such as alumina.

The thermoelectric-element couples each consisting of a couple of p-type and n-type thermoelectric elements may be connected either in parallel or in series provided that the connection allows electric current to flow in opposite directions in the p-type and n-type thermoelectric elements. However, they are usually connected in series in order to secure a sufficiently generated voltage and to reduce the consumed current at the time of cooling.

FIG. 9 shows a production method of Thermoelectric device A The process is explained as follows:

(a) A wafer 6 of an n-type thermoelectric material is obtained by slicing a block sintered body of a thermoelectric material.

(b) The wafer 6 is polished to be plated with a soldering material 7 on both sides.

(c) The wafer 6 is diced into the shape of a quadrangular prism to obtain a plurality of n-type thermoelectric elements 1.

(d) Individual n-type thermoelectric elements 1 and similarly prepared p-type thermoelectric elements 2 are arranged alternately in a matrix.

(e) The arranged thermoelectric elements are sandwiched between two substrates 4 on which electrodes 3 are formed. They are heated to bond the thermoelectric elements to the electrodes 3 through the soldering materials 7.

Thermoelectric device A has an insufficient limitation in reducing the size of the thermoelectric element because the thermoelectric element is processed one by one. In Thermoelectric device A, the most common size of the thermoelectric element is 500 to 4,000 μm or so in the X and Y directions and 500 to 4,000 μm or so in the Z direction (height). At present, it is difficult to obtain a size less than 500 μm.

The other type of the thermoelectric devices is represented by a thermoelectric device stated in the published Japanese patent application Tokukaihei 8-46251. This type is referred to as Thermoelectric device B. Thermoelectric device B is devised in a quest to miniaturize the thermoelectric element. FIG. 10 shows a production method of Thermoelectric device B. The process is explained as follows:

(a) Electrodes 11 are formed on an Si substrate 10.

(b) A mask 12 provides a patterning.

(c) The holes in the mask 12 are filled with bonding materials 13 made of, for example, Ag paste.

(d) A wafer 14 is obtained by polishing a block sintered body of, for example, an n-type thermoelectric material. The wafer 14 is bonded through the bonding materials 13 to the electrodes 11 formed on the Si substrate 10.

(e) The wafer 14 of the thermoelectric material bonded to the Si substrate 10 is further polished until it acquires proper thickness.

(f) Thermoelectric elements 15 having the shape of a quadrangular prism are formed by dicing such that they are arranged in lines.

(g) The other faces of the n-type thermoelectric elements 15 are bonded to a similarly prepared Si substrate 17 having, in this case, p-type thermoelectric elements 16. This concludes the production of the thermoelectric device.

In Thermoelectric device B thus produced, the size of the thermoelectric element in the X and Y directions can be reduced to 250 μm or less, possibly 80 μm or so at the minimum. However, because the above-described process produces the thermoelectric elements by dicing such that the thermoelectric elements having the same type are arranged in lines, four thermoelectric elements nearest to an n-type thermoelectric element 15 or to a p-type thermoelectric element 16 are at most two n-type elements and at most two p-type elements as shown in FIG. 11. Consequently, some of the electrodes 11 connecting a couple of an n-type thermoelectric element 15 and a p-type thermoelectric element 16 in series cannot have a simple shape such as a rectangle or a rounded rectangle. As a result, they become narrower or longer than the standard size, resulting in an increase in wiring resistance.

On the other hand, a method for producing elements having a minute structure has been disclosed in the published Japanese patent application Tokukaihei 11-274592, though this method is for the production of piezoelectric elements. FIG. 12 shows a production method of the elements. The process is explained as follows:

(a) A pattern is provided on one side of an Si substrate 20 with photoresist 21. A plurality of holes 22 are provided on the Si substrate 20 by the selective vapor-phase reaction method.

(b) After the removal of the photoresist 21, the holes 22 are filled with slurry 23 comprising a powder of the piezoelectric element and a binder.

(c) The slurry 23 is sintered to form piezoelectric elements 24.

(d) Only the Si substrate 20 is removed from the obtained composite of the Si substrate 20 and the piezoelectric elements 24 by the selective vapor-phase reaction method. Thus, the columnar piezoelectric elements 24 are obtained.

This method has a limitation in that only one type of material is allowed to produce the columnar structure. In this method, however, the size of the obtained piezoelectric elements in the X and Y directions can be reduced to 250 μm or less, possibly 20 μm or so at the minimum. Furthermore, the shape of the columnar piezoelectric elements on the XY-plane can be selected arbitrarily.

The market has required the miniaturization and densification of thermoelectric devices in recent years. For example, in a power-generating device, because one couple of n-type and p-type thermoelectric elements produces a minimal amount of thermo-electromotive force, it is necessary to connect a multitude of thermoelectric-element couples in series in order to obtain sufficient electromotive force. As a result, a thermoelectric device having a structure in which thermoelectric elements are sandwiched between two ceramic substrates becomes large, thereby making the heat-flow design difficult.

In order to increase the cooling efficiency of a thermoelectric device mounted on an optical module, it is necessary to further increase the mounting density of the couples of n-type and p-type thermoelectric elements. In particular, the increase in the cooling efficiency of thermoelectric devices by their miniaturization and densification has been strongly required in optical modules that incorporate devices such as exciting light sources for optical-fiber amplifiers used in trunk lines, light sources highly capable of controlling wavelengths used in D-WDM systems, transmitters for sending high-speed signals, modulators for controlling light, and optical semi-conductor amplifiers.

However, it is difficult to decrease the size of the thermoelectric element in the X and Y directions to less than 500 μm with the structure of the above-described conventional Thermoelectric device A. On the other hand, the thermoelectric element can be miniaturized with the structure of the conventional Thermoelectric device B. However, because the thermoelectric elements of Thermoelectric device B are produced by dicing such that the thermoelectric elements having the same type are arranged in lines, four thermoelectric elements nearest to an n-type thermoelectric element or to a p-type thermoelectric element are at most two n-type elements and at most two p-type elements. Consequently, some of the electrodes connecting a couple of an n-type thermoelectric element and a p-type thermoelectric element in series become narrower or longer than the standard size, thereby producing the drawback of an increase in wirng resistance.

In addition, it is known that a production method of miniaturized piezoelectric elements has been disclosed in the foregoing Tokukaihei 11-274592. This method, however, limits the element material to one type, which means it cannot allow the sintering of two types of materials as in the case of n-type and p-type thermoelectric elements used in a thermoelectric device.

### SUMMARY OF THE INVENTION

An object of the present invention is to solve the above-described problems by offering (a) a thermoelectric device that can realize the miniaturization and increase in mounting density of thermoelectric elements and maintain low wiring resistance by incorporating orthogonally arranged n-type and p-type thermoelectric elements, (b) an optical module incorporating the thermoelectric device, and (c) a production method therefor.

In order to achieve the above-described object, the present invention offers a thermoelectric device in which:

(a) n-type and p-type thermoelectric elements are arranged orthogonally and alternately, on the XY-plane, in a matrix consisting of at least four elements in total in a row and at least four elements in total in a column;

(b) the size of all the thermoelectric elements is at most 250 μm in the X and Y-directions;

(c) at most four thermoelectric elements nearest to an n-type thermoelectric element are of p type; and

(d) at most four thermoelectric elements nearest to a p-type thermoelectric element are of n type.

In the thermoelectric device of the present invention, the thermoelectric elements are bonded through metallic bonding materials to electrodes having the shape of a rectangle or a rounded rectangle formed on the XY-plane of insulating substrates.

The thermoelectric device of the present invention is produced by a method including the following steps:

(1) A photoresist pattern is provided on one side hereinafter referred to as “the front side”) of a base material, and the front side is etched to form a multitude of regularly arranged small holes.

(2) Another photoresist pattern is provided on the other side (hereinafter referred to as “the reverse side”) of the base material, and the reverse side is etched to form a multitude of regularly arranged small holes such that individual small holes are placed, in the X and Y directions, alternately with individual small holes formed at the front side of the base material.

(3) An n-type thermoelectric material or a p-type thermoelectric material is filled into the small holes at the front side of the base material.

(4) A thermoelectric material having the type opposite to that used at the front side is filled into the small holes at the reverse side of the base material.

(5) The thermoelectric materials filled in the base material are heated without separating the base material.

(6) Both sides of the base material are polished to expose the top and bottom faces of the n-type and p-type thermoelectric elements.

The method for producing the thermoelectric device may further include in succession to the foregoing step (6) the following steps:

(7) The exposed top and bottom faces of the n-type and p-type thermoelectric elements are bonded to insulating substrates through the electrodes.

(8) The base material is removed.

In addition, the foregoing steps (1) and (2) may be replaced by the following steps:

(a) A photoresist pattern is provided on both sides of the base material.

(b) Both sides of the base material are etched concurrently to form a multitude of regularly arranged small holes at both sides of the base material.

It is desirable that the base material be made of any of SiC, Si₈N₄, AlFe₈, Fe, FeNi, quartz glass, glass consisting mainly of quartz, and Si.

The present invention also offers an optical module in which the above-described thermoelectric device of the present invention is bonded to the bottom plate of a package provided with an optical fiber. This module mounts on the thermoelectric device any of at least one LD, at least one semiconductor amplifier, and at least one semiconductor modulator.

The optical module of the present invention is produced by the following method:

First, the thermoelectric device is produced by a process including the following steps:

(1) A photoresist pattern is provided on the front side of a base material, and the front side is etched to form a multitude of regularly arranged small holes.

(2) Another photoresist pattern is provided on the reverse side of the base material, and the reverse side is etched to form a multitude of regularly arranged small holes such that individual small holes are placed, in the X and Y directions, alternately with individual small holes formed at the front side of the base material.

(3) An n-type thermoelectric material or a p-type thermoelectric material is filled into the small holes at the front side of the base material.

(4) A thermoelectric material having the type opposite to that used at the front side is filled into the small holes at the reverse side of the base material.

(5) The thermoelectric materials filled in the base material are heated without separating the base material.

(6) Both sides of the base material are polished to expose the top and bottom faces of the n-type and p-type thermoelectric elements.

(7) The exposed top and bottom faces of the n-type and p-type thermoelectric elements are bonded to the insulating substrates through the electrodes.

(8) The base material is removed.

Second, the produced thermoelectric device is bonded to the bottom plate of a package.

As described above, the present invention enables the miniaturization and increase in mounting density of thermoelectric elements and can decrease the wiring resistance by incorporating orthogonally arranged n-type and p-type thermoelectric elements. As a result, the present invention can offer a compact thermoelectric device and a compact, large-output optical module incorporating the thermoelectric device.

### BRIEF DESCRIPTION OF THE DRAWINGS

In the drawings:

FIG. 1 is a side view showing the basic structure of the thermoelectric device of the present invention, in which (a) shows the arrangement of the electrodes on the top face of the thermoelectric elements and (b) shows that on the bottom face;

FIG. 2 is a schematic cross-sectional view showing the first half of the process for producing the thermoelectric device of the present invention, in which a mold for forming thermoelectric elements is produced.

FIG. 3 is a schematic cross-sectional view showing the second half of the process for producing the thermoelectric device of the present invention, in which the mold forms the thermoelectric elements, and other steps are performed to complete the thermoelectric device;

FIG. 4 is a graph showing the temperature and pressure-control programs with the passage of time at the time of sintering of the thermoelectric elements in an example;

FIG. 5 is scanning electron microscope (SEM) micrograph (at ×100 magnification) showing one type of the thermoelectric elements formed integrally in an Si mold;

FIG. 6 is a schematic cross-sectional view showing a state during the production of an optical module;

FIG. 7 is a schematic perspective view showing the basic structure of an optical module;

FIG. 8 is a schematic perspective view showing the basic structure of the conventional Thermoelectric device A;

FIG. 9 is a process diagram showing the production method of the conventional Thermoelectric device A;

FIG. 10 is a process diagram showing the production method of the conventional Thermoelectric device B;

FIG. 11 is a side view showing the basic structure of the conventional Thermoelectric device B, in which (a) shows the arrangement of the electrodes on the top face of the thermoelectric elements and (b) shows that on the bottom face; and

FIG. 12 is a process diagram showing a method for producing miniaturized thermoelectric elements.

### DETAILED DESCRIPTION OF THE INVENTION

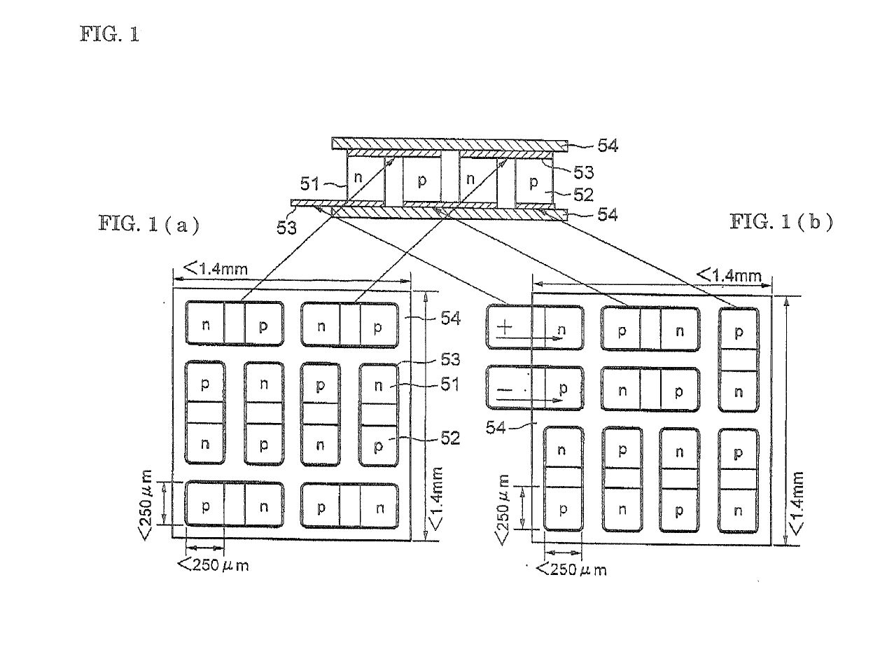

FIG. 1 shows a basic structure of the thermoelectric device of the present invention. The thermoelectric device is broadly classified as Thermoelectric device A described above. In the thermoelectric device, n-type thermoelectric elements 51 and p-type thermoelectric elements 52 are arranged orthogonally and alternately, on the XY-plane, in a matrix consisting of at least four elements in total in a row and at least four elements in total in a column. Couples of neighboring thermoelectric elements 51 and 52 are connected either at their top faces or at their bottom faces through electrodes 53 provided on an insulating substrate 54. Two electrodes 53 have a protrusion from the substrate 54 for connecting a lead.

In the thermoelectric device of the present invention, neighboring n-type thermoelectric elements 51 and p-type thermoelectric elements 52 are connected at their top faces to form couples as shown in FIG. 1(a) and are connected at their bottom faces to form the other couples as shown in FIG. 1(b). The connections are performed through the electrodes 53 formed on the XY-plane of a substrate 54. The thermoelectric elements are bonded to the electrodes 53 through metallic bonding materials (not shown). As can be seen in FIG. 1, at most four thermoelectric elements nearest to an n-type thermoelectric element 51 are of p type and at most four thermoelectric elements nearest to a p-type thermoelectric element 52 are of n type. This arrangement can achieve the miniaturization and densification of the thermoelectric device with a concurrent reduction in wiring resistance.

More specifically, the miniaturization and densification of the thermoelectric device can be achieved because the size of all the n-type thermoelectric elements 51 and the p-type thermoelectric elements 52 in the X and Y-directions can be reduced to 250 μm or less. It is desirable and possible to reduce the size to 80 μm, 40 μm, or less. The wiring resistance produced by the electrodes can be reduced because all the electrodes 53 connecting thermoelectric elements 51 and 52 can be formed on the XY-plane of a substrate 54 with a uniform shape of a rectangle or a rounded rectangle without providing narrower or longer electrodes.

The wiring resistance can be further reduced by forming the electrodes 53 with a low-resistivity material such as Cu, Al, Ag, or Au. It is desirable that the metallic bonding material that bonds thermoelectric elements 51 and 52 to the electrodes 53 contain at least 97 wt. % of any of Sn, Pb, PbSn, SnSb, SnCu, SnCuNi, AuSn, AuGe, AuSi, and Au. The use of these metallic bonding materials provides a good soldering quality, thereby enabling a further reduction in wirng resistance.

It is desirable that the insulating substrate 54 be made of any of highly heat-conductive AlN, beryllia, and alumina. The use of these materials improves the heat-dissipating quality of the thermoelectric elements 51 and 52, thereby enabling a further improvement in the performance of the thermoelectric device; for example, the consumption of electric power can be further reduced.

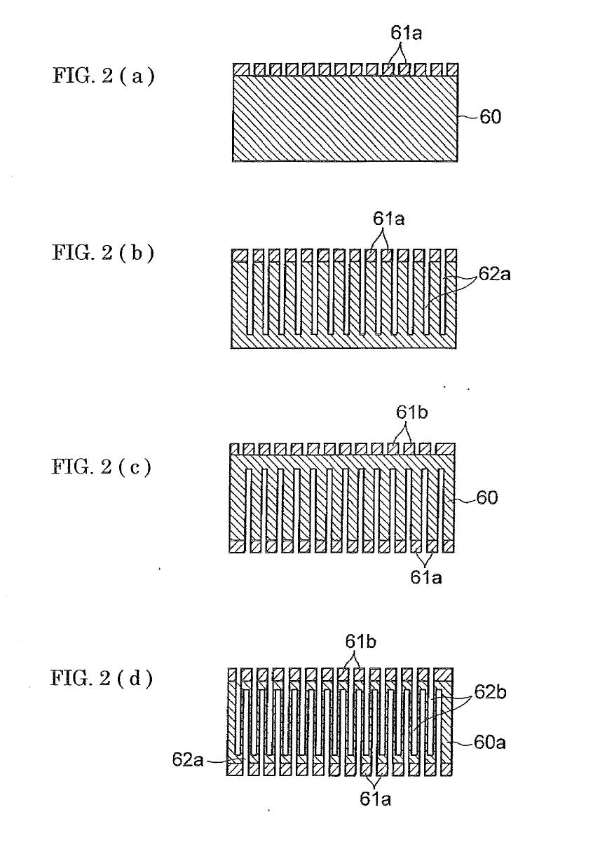

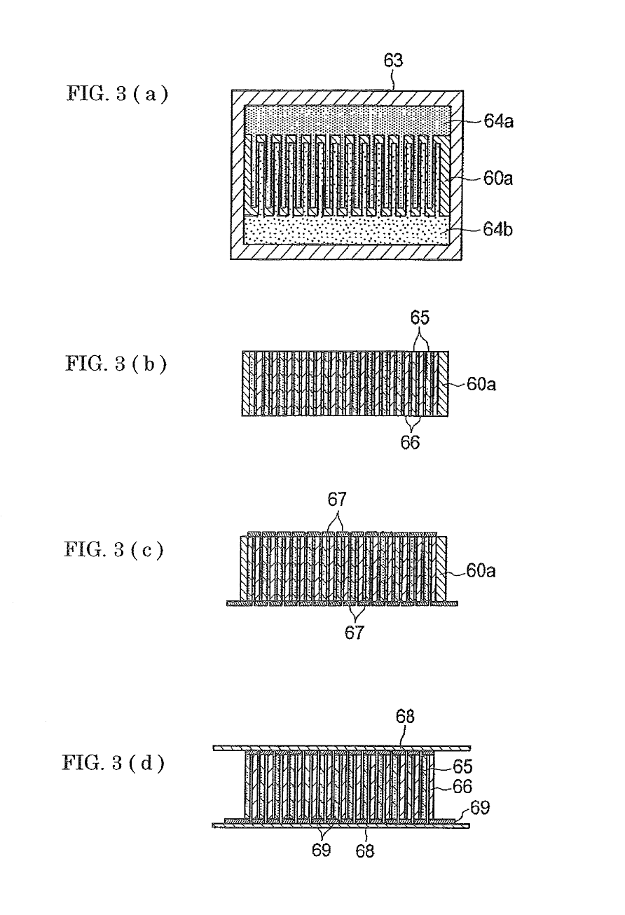

The method for producing the thermoelectric device of the present invention is explained below by referring to FIGS. 2 and 3. The first half of the process is illustrated in FIG. 2 and explained in the following:

(a) A photoresist pattern 61a is provided by photolithography on the front side of a base material 60 such as an Si wafer.

(b) A multitude of regularly arranged small holes 62a are formed by etching.

(c) Similarly, a photoresist pattern 61b is provided on the reverse side of the base material 60.

(d) A multitude of regularly arranged small holes 62b are formed by etching such that individual small holes 62b are placed, in the X and Y-directions, alternately with individual small holes 62a formed at the front side.

Alternatively, a multitude of regularly arranged small holes can be formed concurrently at both sides of the base material by providing a photoresist pattern on both sides of the base material and etching both sides of the base material concurrently.

The second half of the process is illustrated in FIG. 3 and explained in the following:

(a) A mold 60a is obtained by removing the photoresist patterns 61a and 61b. An n-type (or a p-type) thermoelectric material 64a is filled into the small holes 62a at the front side of the mold 60a and a p-type (or an n-type) thermoelectric material 64b is filled into the small holes 62b at the reverse side. The sintering of the thermoelectric materials 64a and 64b filled in the mold 60a without separating the mold 60a forms n-type and p-type thermoelectric elements in the small holes 62a and 62b, respectively. FIG. 3(a) illustrates the method in which a glass capsule 63 houses powders of the thermoelectric materials 64a and 64b loaded into their corresponding sides of the mold 60a to perform the pressure-filling and sintering of the powders by the hot-isostatic-pressing (HIP) method. This step, however, has various alternatives as shown below:

(1) The thermoelectric materials may be filled by the infiltration method.

(2) The sintering may be performed separately after the thermoelectric materials are filled.

(3) The thermoelectric elements may be single-crystalline, polycrystalline, or amorphous bodies formed by the vapor-phase epitaxy (VPE) or liquid-phase epitaxy (LPE) method.

(b) Both sides of the mold 60a are polished to expose the top and bottom faces of the n-type thermoelectric elements 65 and the p-type thermoelectric elements 66.

(c) Metallic bonding materials 67 are applied to the top and bottom faces of the n-type thermoelectric elements 65 and the p-type thermoelectric elements 66.

(d) The thermoelectric elements are bonded at both their faces to the electrodes 69 formed on circuit substrates 68 through the metallic bonding materials 67. The mold 60a is removed by, for example, etching to complete the production of the thermoelectric device.

The material for the base material to be used in the production method of the present invention must have a melting point higher than the sintering temperature of the thermoelectric materials, specifically at lowest 650° C. It is desirable that the material for the base material be SiC, Si₃N₄, Si, AlFe₈, Fe, FeNi, quartz glass, or glass consisting mainly of quartz. Of these, Si is particularly desirable because it has a high Young's modulus suitable for the formation of minute thermoelectric elements.

The thermoelectric device of the present invention can be mounted on an optical module to produce a compact, high-performance optical module. More specifically, an optical module can be produced by the following process:

(a) A thermoelectric device of the present invention produced by the above-described method is bonded to the bottom plate of a package.

(b) One or more LDs, one or more semiconductor amplifiers, or one or more semiconductor modulators are mounted on the thermoelectric device.

(c) An optical fiber is connected by yttrium-aluminum-garnet (YAG) laser-beam welding to the window of the package to complete the production.

### EXAMPLE

### (1) Production of Mold for Forming Thermoelectric Elements

As shown in FIG. 2(a), an Si wafer having a thickness of 600 μm was prepared as a base material 60. A photoresist pattern 61a made of an organic substance was formed on the front side of the Si wafer by photolithography. Small holes formed in the photoresist 61a had the shape of a square. As shown in FIG. 2(b), only the front side of the base material 60 was treated by reactive-ion etching using SF₆ as an Si-reactive ion gas and C₄F₈ as a protective gas for the walls of the small holes. This treatment formed quadrangular prism-shaped small holes 62a, each having a square cross section with a side length of 40 μm and a depth of 500 μm, regularly arranged in the X and Y directions with a pitch of 120 μm.

A gas to be used for the reactive-ion etching of the base material has only to be capable of etching it. In the case of an Si base material, not only SF₆ but also other reactive ion gases such as XeF₂ can be used. When a large photoresist pattern is used, an etching liquid such as a KOH solution can also be used Even when an etching liquid is used, small holes having a square cross section with a side length of 250 μm and a depth of 100 μm can be formed regularly with a pitch of 300 μm. The cross-sectional shape of the small holes is not limited to a square, but may be extended to any shape such as a circle.

As shown in FIG. 2(c), a photoresist pattern 61b was formed on the reverse side of the Si wafer (the base material 60) with reference to the small holes 62a formed on the front side. The positioning was performed to a precision of 1.5 μm or less. Since this value was significantly small in comparison with the 40-μm side length of the square cross section of the small holes 62a, the positioning can be said to be high in precision.

After the formation of the photoresist pattern 61b, the reverse side was etched by using XeF₂ as an Si-reactive ion gas. As shown in FIG. 2(d), the etching formed quadrangular prism-shaped small holes 62b, each having a square cross section with a side length of 40 μm and a depth of 500 μm, regularly arranged in the X and Y directions with a pitch of 120 μm. The obtained Si mold 60a had a multitude of small holes 62a and 62b on the front and reverse sides, respectively, with the small holes 62a and 62b being separated from each other without failure.

In the above-described example, Si was used as the base material 60. However, any material may be used providing that it can be removed by selective etching, has proper hardness as in the case of Si, and has a melting point of at lowest 650° C. For example, the following materials may be used: a ceramic materiel such as SiC or Si₃N₄, a metallic material such as AlFe₈, Fe, or FeNi, and glass such as quartz glass or glass consisting mainly of quartz. These materials can also be etched selectively.

### (2) Production of Thermoelectric Elements With the Use of Si Mold

The powders of the n-type and p-type thermoelectric materials to be filled into the Si mold 60a were produced by crushing ingots of a mixed-crystalline material consisting mainly of Bi, Sb, Se, and Te and including I, Cu, Zn, and Pb as impurities. The powders were subjected to a mechanical-alloying treatment to achieve a powder diameter of 20 μm or less.

As shown in FIG. 3(a), the powder of the n-type thermoelectric material 64a was filled into the small holes 62a provided on the front side of the Si mold 60a, and the powder of the p-type thermoelectric material 64b was filled into the small holes 62b provided on the reverse side. The powders were pressure-filed and formed at a rate of 1 gram per 10-millimeter square under a pressure of 50 MPa at both sides concurrently. Subsequently, the powders of the thermoelectric materials 64a and 64b were vacuum-packaged in a glass tube 63 without separating the mold 60a. The glass tube 63 was placed in a boron-nitride (BN) container to be heated under pressure in an argon atmosphere. Thus, the powders of the thermoelectric materials 64a and 64b were sintered.

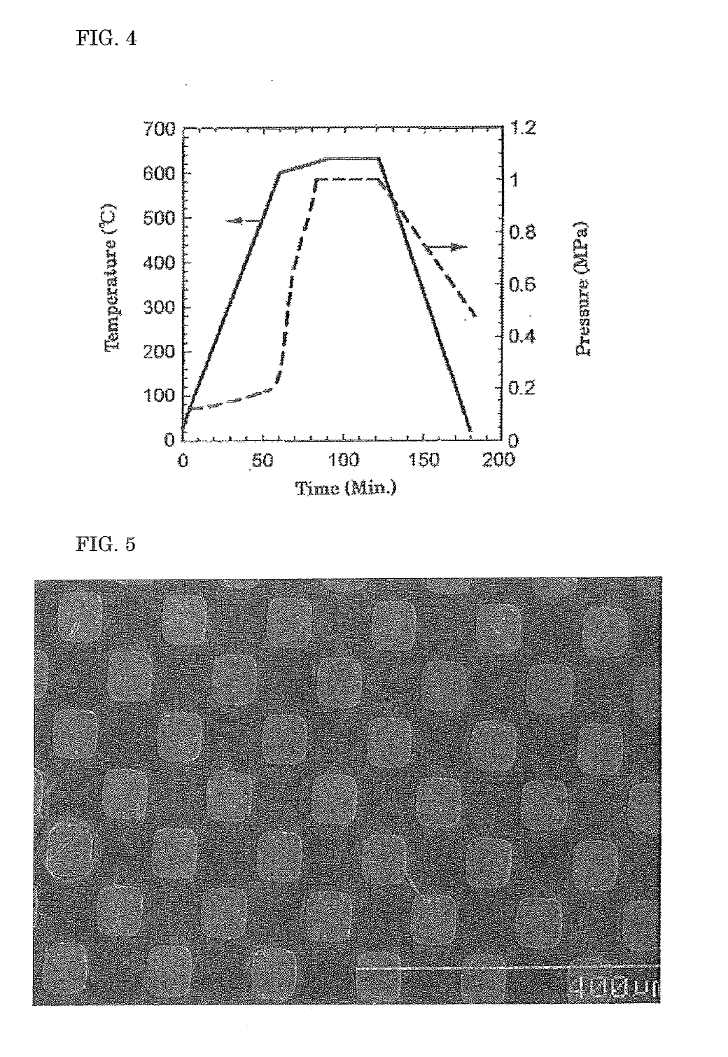

FIG. 4 is a graph showing the temperature- and pressure-control programs with the passage of time at the time of the sintering. The temperature was raised linearly up to 600° C., which is close to the melting point of the thermoelectric elements. Subsequently, while the temperature was raised to 630° C., the pressure was raised from 0.14 to 1 MPa to pressurize the vacuum-packaged glass tube 63 from the outside. The temperature and pressure were maintained at 630° C. and 1 MPa, respectively, for 30 minutes. Then, while the temperature was decreased at a rate of 10° C./min., the pressure was decreased.

As shown in FIG. 3(b), both sides were polished concurrently together with the Si mold 60a to polish away a thickness of 50 μm at each side. The polishing exposed at both sides of the mold 60a the top and bottom faces of the n-type thermoelectric elements 65 and the p-type thermoelectric elements 66, each having a square cross section with a side length of 40 μm and a length (height) of 400 μm. In other words, the polishing produced the n-type thermoelectric elements 65 and the p-type thermoelectric elements 66 integrated with the Si mold 60a. FIG. 5 is an SEM micrograph of the thermoelectric elements taken when the polishing proceeded to the extent that one side of the Si mold 60a appeared. This method can produce even larger thermoelectric elements providing that they have the same aspect ratio as the above-described example. The same aspect ratio can be obtained by combinations such as a square cross section with a side length of 100 μm and a length (height) of 1 mm and a square cross section with a side length of 200 μm and a length (height) of 2 mm.

As shown in FIG. 3(c), a photoresist pattern was formed by photolithography on the top and bottom faces of the n-type thermoelectric elements 65 and the p-type thermoelectric elements 66 exposed at both sides of the Si mold 60a. Both the faces were plated with metallic bonding materials 67 as a soldering material. The metallic bonding materials 67 may be made of Sn, Pb, PbSn, SnSb, SnCu, SnCuNi, AuSn, AuGe, AuSi, or Au. All of these materials showed good wettability with the thermoelectric element and a bonding resistance as small as at most one-tenth the bulk resistance of the thermoelectric element. The metallic bonding materials can also be provided on the faces by the metallization process using a method such as vapor deposition. After the plating, a plurality of thermoelectric elements 65 and 66 were diced together with the Si mold 60a to obtain chips having the specified size and shape.

### (3) Production of Ceramic Substrate Having Electrodes

The substrate of a thermoelectric device may be made of any insulating material such as ceramic. However, it is particularly desirable to use highly heat-conductive alumina, AlN, and beryllia. AlN and beryllia are superior to alumina in terms of thermal conductivity. A computer simulation revealed that the changing of a substrate from alumina to beryllia or AlN reduces the power consumption of the thermoelectric device by at least 15%. However, it is difficult to handle beryllia because of its adverse effects such as the production of cancer. Consequently, AlN was used as the substrate in this example.

After an AlN substrate was sintered, its surface was polished. Subsequently, layers of Ti, Pt, and Ni or layers of Cr, Mo, and Ni were formed on one side of the substrate by vapor deposition or sputtering. Ti or Cr was used as the first layer on the ceramic substrate in order to improve the bonding quality between the ceramic and metal. Pt or Mo was used as a buffer layer in order to prevent a reduction in the bonding strength. If no buffer layer is used, metals at the top and bottom of the first layer may be alloyed by heat to alter the first layer and reduce the bonding strength. Ni was used as the surface layer in order to exploit its good quality in bonding with other metals. This layer facilitates subsequent metallization.

A resist pattern was formed on the Ni layer by photolithography. The resist layer had a thickness of 140 μm, a wiring width of 40 μm, and a wiring pitch of 60 μm. A substrate provided with the resist was plated with Cu in order for the Cu to deposit and grow selectively at the place where no resist was formed. The plating was continued until the Cu layer reached a thickness of 145 μm. Then, the Cu layer was polished together with the resist to achieve a thickness of 135 μm.

The substrate having the resist and Cu layer was subjected to an ashing treatment with oxygen to provide gaps between the side faces of the Cu portions and the resist. All the surfaces having no resist were plated with Au. The resist was removed with an organic solvent. The Ti—Pt—Ni or Cr—Mo—Ni composite layer having no Cu layer was removed from the substrate by the selective etching between the Au and the other metals. Thus, a regularly arranged electrode pattern was formed. The AlN substrate was divided by dicing to form circuit substrates for thermoelectric devices.

Although Cu electrodes were used in the above example, Al, Ag, or Au can also be used to form the electrodes by a similar method. The above example achieved high bonding strength between the electrode and the ceramic material. The obtained circuit substrate was resistant to thermal stress and therefore highly reliable.

### (4) Production of Thermoelectric Device

Two circuit substrates provided with electrodes formed by the above-described method were prepared, and flux was applied to both substrates. Diced thermoelectric elements 65 and 66 having a unified mold 60a as shown in FIG. 3(c) were sandwiched between the two circuit substrates. The metallic bonding materials 67 formed on the top and bottom faces of the thermoelectric elements 65 and 66 were melted on a hot plate to concurrently bond all the thermoelectric elements 65 and 66 to the electrodes provided on the circuit substrates. The alignment at the time of bonding was performed by producing the circuit substrate with the same size as that of the Si mold 60a unified with the thermoelectric elements 65 and 66. Good soldering was achieved between all the electrodes and the thermoelectric elements 65 and 66.

As shown in FIG. 3(d), the foregoing bonded body was etched by using XeF₂ to selectively remove the Si mold 60a. In this process, a mixed liquid of hydrofluoric acid and nitric acid may be used instead of XeF₂ which is relatively high-cost. A similar selective etching can be carried out even when the base material, or mold, is made of a ceramic materiel such as SiC or Si₃N₄, a metallic material such as AlFe₈, Fe, or FeNi, or glass such as quartz glass or glass consisting mainly of quartz. After the above-described selective etching, leads were bonded to the device by using low-melting-point BiSn solder to complete the production of the thermoelectric device.

When a plated layer as thick as at least 50 μm is provided as the soldering agent by using a metallic bonding material such as Sn, Pb, PbSn, SnSb, SnCu, SnCuNi, AuSn, AuGe, AuSi, or Au, even if the Si mold is removed by etching before the thermoelectric elements are solder-bonded to the circuit substrates, the metallic bonding material can sufficiently support the thermoelectric elements and thus enables them to be solder-bonded to the circuit substrates. When this method is employed, the absence of substrates enables the etching agent to quickly pervade the mold, reducing the etching time.

When used as a power-generating device, the thermoelectric device exhibited an excellent performance of generating a voltage of at least 20 V and supplying a current of at least 0.1 A. When used as a cooling device, it not only reduced the wiring resistance by 5% in comparison with the above-described Thermoelectric device B but also increased the yields of the thermoelectric element and circuit substrate, decreasing the manufacturing cost. The thermoelectric device increased the cooling density at the substrate surface by a factor of at least five. As a result, the thermoelectric device achieved miniaturization and high performance.

### (5) Production of Optical Module

In optical semiconductor devices, particularly optical semiconductor modules such as optical semiconductor laser modules for optical-fiber amplifiers, packages are used for hermetically housing optical semiconductors, driver ICs, and other devices.

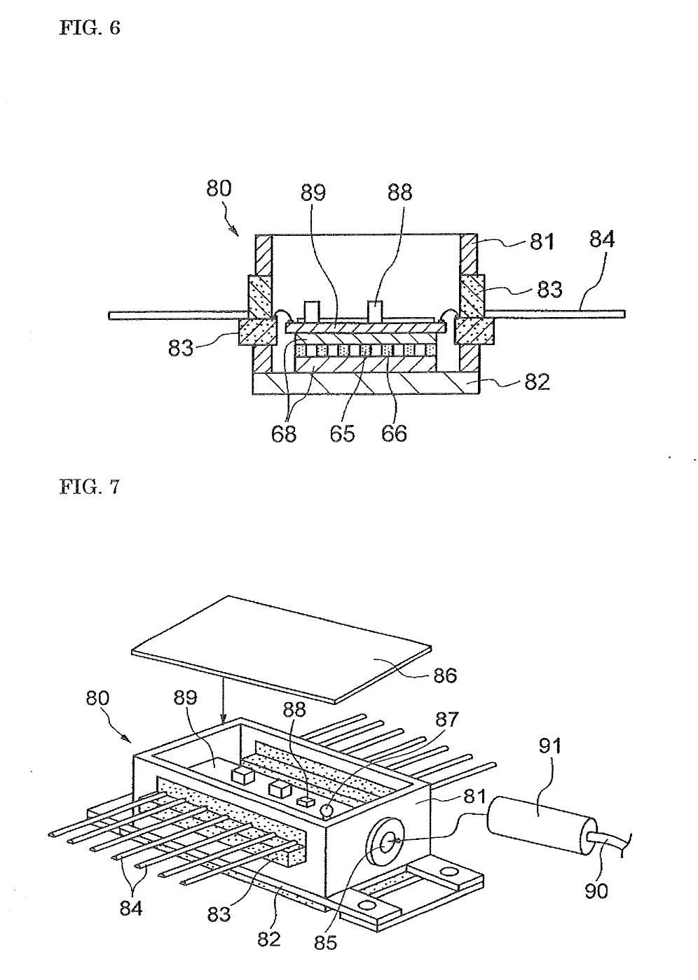

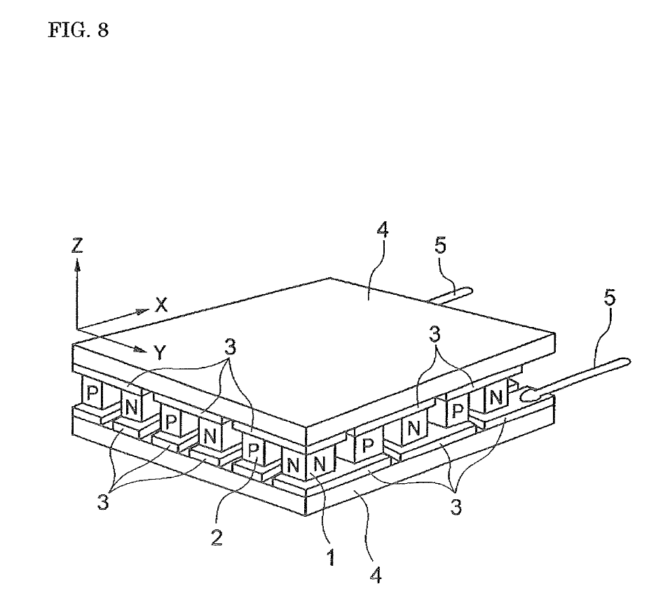

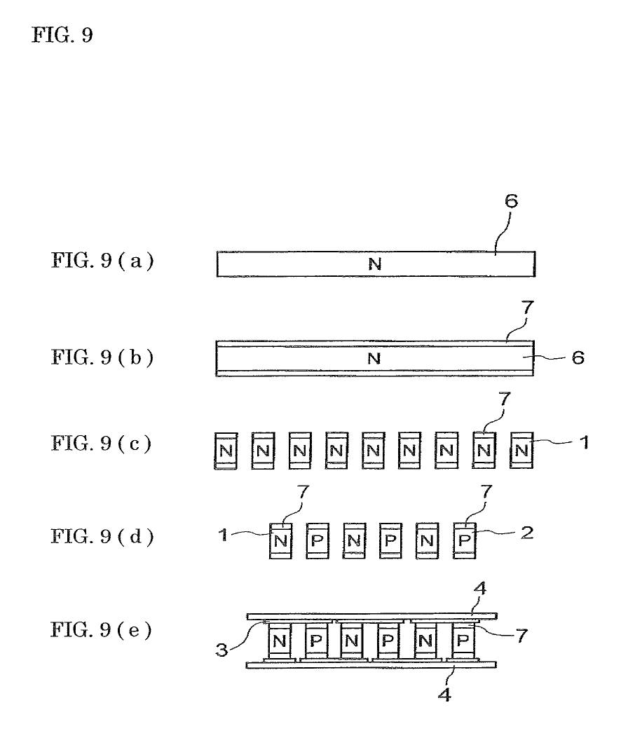

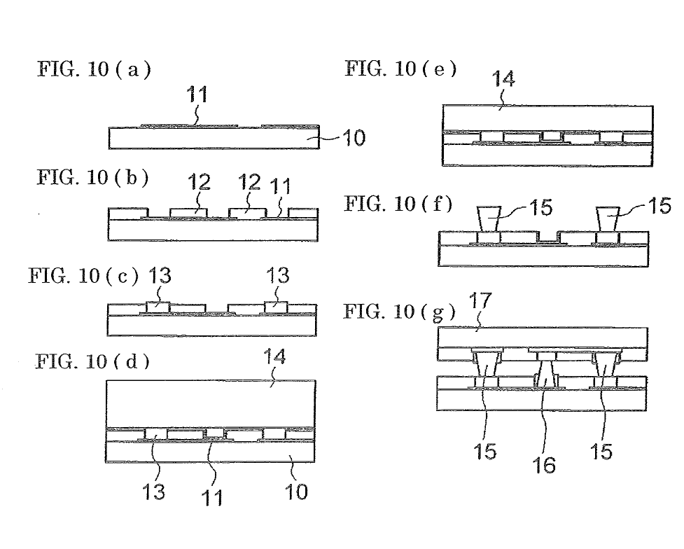

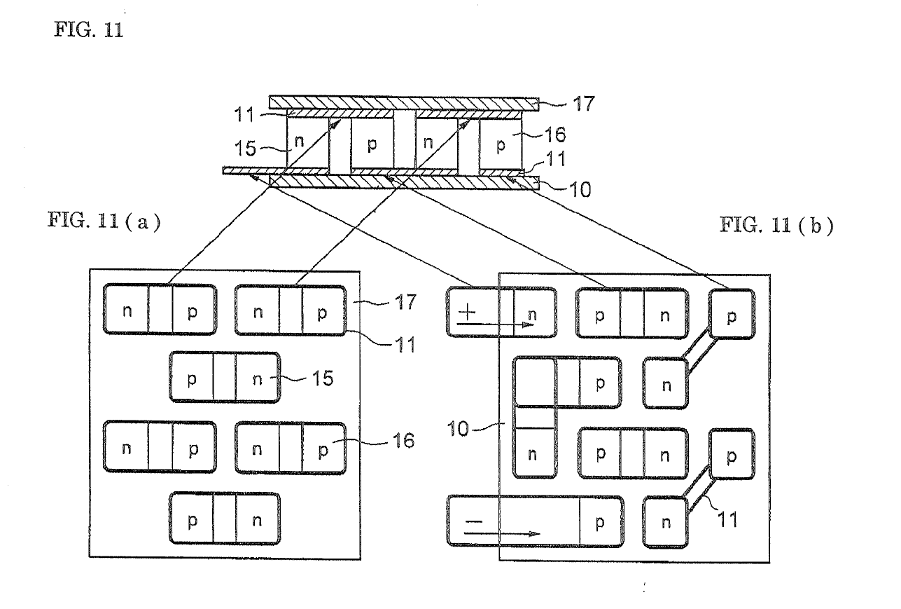

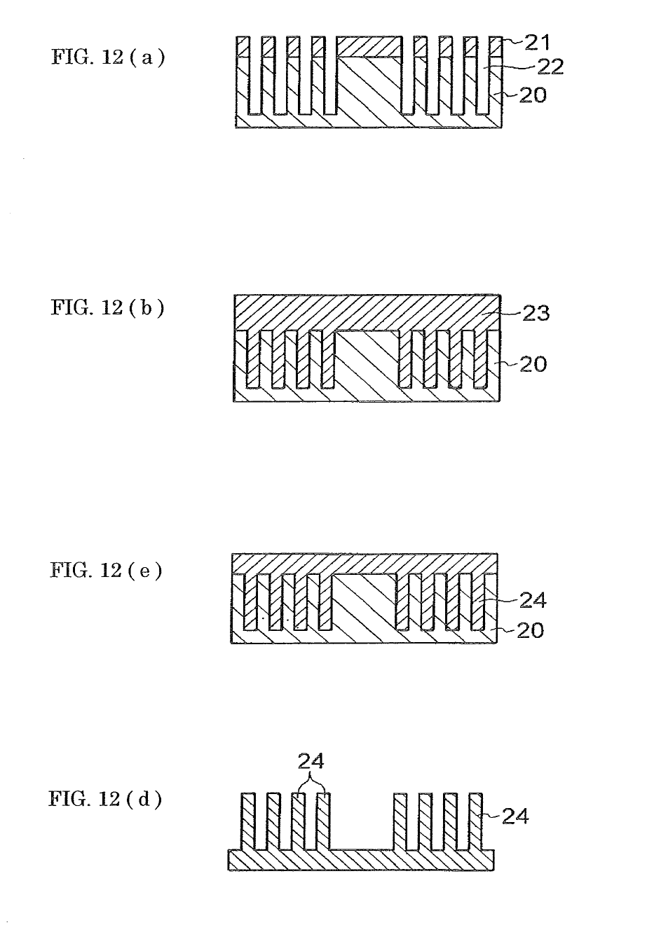

For example, as shown in FIGS. 6 and 7, generally, a package 80 has a structure in which a frame 81 made of, for example, an Fe—Ni—Co alloy (brand name: Cobar) is bonded to a bottom plate 82 made of a material such as an Fe—Ni—Co alloy, an Fe—Ni alloy (brand name: 42 alloy), a ceramic material such as AlN, or a composite metal material such as CuW. The frame 81 acting as the side walls of the package 80 has partly metallized ceramic terminal portions 83 composed of a ceramic sheet. A plurality of Cobar terminal leads 84 are provided on the ceramic terminal portions 83. The frame 81 also has a window 85 that allows the transmittance of light.

The members such as the frame 81, the bottom plate 82, the ceramic terminal portions 84, and the window 85 are assembled by silver-alloy brazing or soldering. The assembled package 80 is plated with Au throughout its surface in order to hermetically seal it with a lid 86 at the final step, to prevent it from corroding, and to facilitate the soldering for assembling semiconductor modules at a later time.

In this example, the bottom plate 82 was made of AlN, and the package 80 was a butterfly type for optical communication. The main body of the package 80 had a length of 12 mm, a width of 7 mm, and a height of 6 mm. The length and width were one-half those of conventional devices. A thermoelectric device produced by the above-described method was die-bonded to the bottom plate 82 by using InSn. Leads and the terminals of the package were soldered with InSn. Although InSn was used as the solder in this example, soldering materials having excellent strength, such as PbSn, SnCuNi, and SnAgCu, can also be used when the thermoelectric elements 65 and 66 are bonded to the circuit substrates 68 with a metallic bonding material having a high melting point.

Subsequently, a subcarrier 89 in which a lens 87 and an LD are optically coupled was die-bonded to the thermoelectric device. After the LD was connected by wire-bonding, the lid 86 was seam-welded. Finally, an optical fiber 90 was YAG-welded through a ferrule 91 to the window 85 of the package 80. Notwithstanding that the obtained optical module reduced its size by half over conventional devices, it increased its optical output by a factor of 1.5 because of its excellent cooling power.

What is claimed is:

1. A thermoelectric device comprising n-type and p-type thermoelectric elements that:
(a) are arranged orthogonally and alternately, on the XY-plane, in a matrix consisting of at least four elements in total in a row and at least four elements in total in a column;
(b) have a size of at most 250 μm in the X and Y directions; and
(c) are arranged such that at most four thermoelectric elements nearest to an n-type thermoelectric element are of p type and at most four thermoelectric elements nearest to a p-type thermoelectric element are of n type.

2. A thermoelectric device as defined in claim 1, the thermoelectric device further comprising:
(a) at least two insulating substrates; and
(b) a plurality of electrodes that:
(b1) have the shape of one of a rectangle and a rounded rectangle;
(b2) are formed on the XY-plane of the insulating substrates; and
(b3) are bonded to the thermoelectric elements through metallic bonding materials.

3. A thermoelectric device as defined in claim 2, wherein the electrode consists mainly of at least one metal selected from the group consisting of Cu, Al, Ag, and Au.

4. A thermoelectric device as defined in claim 2, wherein the metallic bonding material contains at least 97 wt. % of any of Sn, Pb, PbSn, SnSb, SnCu, SnCuNi, AuSn, AuGe, AuSi, and Au.

5. A thermoelectric device as defined in claim 2, wherein the insulating substrate is made of any of AlN, beryllia, and alumina.

6. A method for producing a thermoelectric device as defined in claim 1, the method comprising the steps of:
(1) providing a photoresist pattern on one side (hereinafter referred to as “the front side”) of a base material and etching the front side to form a multitude of regularly arranged small holes;
(2) providing a photoresist pattern on the other side (hereinafter referred to as “the reverse side”) of the base material and etching the reverse side to form a multitude of regularly arranged small holes such that individual small holes are placed, in the X and Y directions, alternately with individual small holes formed at the front side of the base material;
(3) filling one of an n-type thermoelectric material and a p-type thermoelectric material into the small holes at the front side of the base material;
(4) filling a thermoelectric material having the type opposite to that used at the front side into the small holes at the reverse side of the base material;
(5) heating the thermoelectric materials filled in the base material without separating the base material to form n-type and p-type thermoelectric elements; and
(6) polishing both sides of the base material to expose the top and bottom faces of the n-type and p-type thermoelectric elements.

7. A method for producing a thermoelectric device as defined in claim 2, the method comprising the steps of:
(1) providing a photoresist pattern on the front side of a base material and etching the front side to form a multitude of regularly arranged small holes;
(2) providing a photoresist pattern on the reverse side of the base material and etching the reverse side to form a multitude of regularly arranged small holes such that individual small holes are placed, in the X and Y-directions, alternately with individual small holes formed at the front side of the base material;
(3) filling one of an n-type thermoelectric material and a p-type thermoelectric material into the small holes at the front side of the base material;
(4) filling a thermoelectric material having the type opposite to that used at the front side into the small holes at the reverse side of the base material;
(5) heating the thermoelectric materials filled in the base material without separating the base material to form n-type and p-type thermoelectric elements; and
(6) polishing both sides of the base material to expose the top and bottom faces of the n-type and p-type thermoelectric elements.

8. A method as defined in claim 6, the method further comprising in succession to step (6) the steps of:
(7) bonding the exposed top and bottom faces of the n-type and p-type thermoelectric elements to the insulating substrates through the electrodes; and
(8) removing the base material.

9. A method as defined in claim 7, the method further comprising in succession to step (6) the steps of:
(7) bonding the exposed top and bottom faces of the n-type and p-type thermoelectric elements to the insulating substrates through the electrodes; and
(8) removing the base material.

10. A method for producing a thermoelectric device as defined in claim 1, the method comprising the steps of:
(1) providing a photoresist pattern on both sides of the base material and concurrently etching both sides of the base material to form a multitude of regularly arranged small holes at both sides of the base material;
(2) filling one of an n-type thermoelectric material and a p-type thermoelectric material into the small holes at the front side of the base material;
(3) filling a thermoelectric material having the type opposite to that used at the front side into the small holes at the reverse side of the base material;
(4) heating the thermoelectric materials filled in the base material without separating the base material to form n-type and p-type thermoelectric elements; and
(5) polishing both sides of the base material to expose the top and bottom faces of the n-type and p-type thermoelectric elements.

11. A method for producing a thermoelectric device as defined in claim 2, the method comprising the steps of:
(1) providing a photoresist pattern on both sides of the base material and concurrently etching both sides of the base material to form a multitude of regularly arranged small holes at both sides of the base material;
(2) filling one of an n-type thermoelectric material and a p-type thermoelectric material into the small holes at the front side of the base material;
(3) filling a thermoelectric material having the type opposite to that used at the front side into the small holes at the reverse side of the base material;
(4) heating the thermoelectric materials filled in the base material without separating the base material to form n-type and p-type thermoelectric elements; and
(5) polishing both sides of the base material to expose the top and bottom faces of the n-type and p-type thermoelectric elements.

12. A method as defined in claim 10, the method further comprising in succession to step (5) the steps of:
(6) bonding the exposed top and bottom faces of the n-type and p-type thermoelectric elements to the insulating substrates through the electrodes; and
(7) removing the base material.

13. A method as defined in claim 11, the method further comprising in succession to step (5) the steps of:
(6) bonding the exposed top and bottom faces of the n-type and p-type thermoelectric elements to the insulating substrates through the electrodes; and
(7) removing the base material.

14. A method as defined in claim 6, wherein the base material has a melting point of at lowest 650° C.

15. A method as defined in claim 7, wherein the base material has a melting point of at lowest 650° C.

16. A method as defined in claim 6, wherein the base material is made of any of SiC, Si₃N₄, AlFe₈, Fe, FeNi, quartz glass, glass consisting mainly of quartz, and Si.

17. A method as defined in claim 7, wherein the base material is made of any of SiC, Si₃N₄, AlFe₈, Fe, FeNi, quartz glass, glass consisting mainly of quartz, and Si.

18. An optical module comprising:
(a) a package;
(b) an optical fiber connected to the package;
(c) a thermoelectric device as defined in claim 1, the device being bonded to the bottom plate of the package; and
(d) a member selected from the group consisting of at least one laser-diode (LD), at least one semiconductor amplifier, and at least one semiconductor modulator, the member being mounted on the thermoelectric device.

19. An optical module comprising:
(a) a package;
(b) an optical fiber connected to the package;
(c) a thermoelectric device as defined in claim 2, the device being bonded to the bottom plate of the package; and
(d) a member selected from the group consisting of at least one LD, at least one semiconductor amplifier, and at least one semiconductor modulator, the member being mounted on the thermoelectric device.

20. A method for producing an optical module as defined in claim 18, the method comprising the steps of:
(a) producing the thermoelectric device by a process comprising the steps of:
(a1) providing a photoresist pattern on the front side of a base material and etching the front side to form a multitude of regularly arranged small holes;
(a2) providing a photoresist pattern on the reverse side of the base material and etching the reverse side to form a multitude of regularly arranged small holes such that individual small holes are placed, in the X and Y directions, alternately with individual small holes formed at the front side of the base material;
(a3) filling one of an n-type thermoelectric material and a p-type thermoelectric material into the small holes at the front side of the base material;
(a4) filling a thermoelectric material having the type opposite to that used at the front side into the small holes at the reverse side of the base material;
(a5) heating the thermoelectric materials filled in the base material without separating the base material to form n-type and p-type thermoelectric elements;
(a6) polishing both sides of the base material to expose the top and bottom faces of the n-type and p-type thermoelectric elements;
(a7) bonding the exposed top and bottom faces of the n-type and p-type thermoelectric elements to the insulating substrates through the electrodes; and
(a8) removing the base material; and
(b) bonding the thermoelectric device to the bottom plate of the package.

21. A method for producing an optical module as defined in claim 19, the method comprising the steps of:
(a) producing the thermoelectric device by a process comprising the steps of:
(a1) providing a photoresist pattern on the front side of a base material and etching the front side to form a multitude of regularly arranged small holes;
(a2) providing a photoresist pattern on the reverse side of the base material and etching the reverse side to form a multitude of regularly arranged small holes such that individual small holes are placed, in the X and Y directions, alternately with individual small holes formed at the front side of the base material;
(a3) filing one of an n-type thermoelectric material and a p-type thermoelectric material into the small holes at the front side of the base material;
(a4) filling a thermoelectric material having the type opposite to that used at the front side into the small holes at the reverse side of the base material;
(a5) heating the thermoelectric materials filled in the base material without separating the base material to form n-type and p-type thermoelectric elements;
(a6) polishing both sides of the base material to expose the top and bottom faces of the n-type and n-type thermoelectric elements;
(a7) bonding the exposed top and bottom faces of the n-type and p-type thermoelectric elements to the insulating substrates through the electrodes; and
(a8) removing the base material; and
(b) bonding the thermoelectric device to the bottom plate of the package.
